(19) United States
(12) Patent Application Publication
(10) Pub. No.: US 2023/0187205 A1
(43) Pub. Date: Jun. 15, 2023

(54) SUBSTRATE PACKAGE WITH GLASS DIELECTRIC

(71) Applicant: Intel Corporation, Santa Clara, CA (US)

(72) Inventors: Ying Wang, Chandler, AZ (US); Chong Zhang, Chandler, AZ (US); Meizi Jiao, Chandler, AZ (US); Junnan Zhao, Gilbert, AZ (US); Cheng Xu, Chandler, AZ (US); Yikang Deng, Chandler, AZ (US)

(73) Assignee: Intel Corporation, Santa Clara, CA (US)

(21) Appl. No.: 18/165,422

(22) Filed: Feb. 7, 2023

Related U.S. Application Data
(63) Continuation of application No. 16/042,203, filed on Jul. 23, 2018.

(51) Int. Cl. H01L 21/02; H01L 23/522; H01L 23/00; H01L 21/768; H01L 23/498

(52) U.S. Cl. CPC H01L 21/02422; H01L 23/5226; H01L 24/09; H01L 24/17; H01L 21/76816; H01L 23/49827; H01L 23/49894

(57) ABSTRACT

Embodiments may relate to a semiconductor package that includes a die and a glass core coupled with the die. The glass core may include a cavity with an interconnect structure therein. The interconnect structure may include pads on a first side that are coupled with the die, and pads on a second side opposite the first side. Other embodiments may be described and/or claimed.

### BACKGROUND

Manufacturing of three dimensional (3D) packages through organic dielectric materials may encounter one or more processing challenges. Specifically, embedding interconnect components in organic dielectric materials may encounter strict limitations with respect to alignment, warp age of the package, or thickness variation. Additional process steps may also need to be applied to manufacture layer-to-layer structures. However, these additional process steps may result in a higher cost of the package, and a higher yield loss during manufacturing.

Some interconnect architectures for 3D packaging may require a manufacturing process flow that involves multiple rounds of planarization. The interconnect architectures may also require additional substrate manufacturing steps after a die or the package is assembled, which may in turn increase the chance of damage to the die. Moreover, many process steps may meet manufacturing issues such as die-bonding film (DBF) undercut caused by wet etch, failure to reveal a via due to package warpage, challenges to reducing pillar pitch, etc.

### BRIEF DESCRIPTION OF THE DRAWINGS

FIG. 1 illustrates a simplified cross-sectional view of an example package with a glass dielectric, in accordance with various embodiments.

FIG. 2 illustrates a simplified cross-sectional view of a technique for making a glass dielectric, in accordance with various embodiments.

FIG. 3 illustrates a simplified cross-sectional view of a technique for making a package with a glass dielectric, in accordance with various embodiments.

FIG. 4 further illustrates a simplified cross-sectional view of a technique for making a package with a glass dielectric, in accordance with various embodiments.

FIG. 5 further illustrates a simplified cross-sectional view of a technique for making a package with a glass dielectric, in accordance with various embodiments.

FIG. 6 further illustrates a simplified cross-sectional view of a technique for making a package with a glass dielectric, in accordance with various embodiments.

FIG. 7 further illustrates a simplified cross-sectional view of a technique for making a package with a glass dielectric, in accordance with various embodiments.

FIG. 8 further illustrates a simplified cross-sectional view of a technique for making a package with a glass dielectric, in accordance with various embodiments.

FIG. 9 further illustrates a simplified cross-sectional view of a technique for making a package with a glass dielectric, in accordance with various embodiments.

FIG. 10 further illustrates a simplified cross-sectional view of a technique for making a package with a glass dielectric, in accordance with various embodiments.

FIG. 11 further illustrates a simplified cross-sectional view of a technique for making a package with a glass dielectric, in accordance with various embodiments.

FIG. 12 illustrates an example technique for making a package with a glass dielectric, in accordance with various embodiments.

FIG. 13 illustrates an example device that may use the package of FIG. 1, 9, or 11, in accordance with various embodiments.

### DETAILED DESCRIPTION

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A or B” means (A), (B), or (A and B). For the purposes of the present disclosure, the phrase “A, B, or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

In various embodiments, the phrase “a first feature formed, deposited, or otherwise disposed on a second feature,” may mean that the first feature is formed, deposited, or disposed over the feature layer, and at least a part of the first feature may be in direct contact (e.g., direct physical or electrical contact) or indirect contact (e.g., having one or more other features between the first feature and the second feature) with at least a part of the second feature.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an application specific integrated circuit (ASIC), an electronic circuit, a processor (shared, dedicated, or group) or memory (shared, dedicated, or group) that execute one or more software or firmware programs, a combinational logic circuit, or other suitable components that provide the described functionality.

Embodiments herein may be described with respect to various Figures. Unless explicitly stated, the dimensions of the Figures are intended to be simplified illustrative examples, rather than depictions of relative dimensions. For example, various lengths/widths/heights of elements in the Figures may not be drawn to scale unless indicated otherwise.

Embodiments herein relate to a 3D package architecture that may include glass dielectrics. Specifically, the package architecture may include a dual-sided interconnect die embedded within cavities of the glass dielectric, as explained in further detail below.

More specifically, embodiments may relate to a manufacturing technique that includes embedding the dual-sided interconnect die in a glass core material with a cavity pre-cut therein. The die may be embedded within the cavity of the glass core material.

Additionally, embodiments way relate to a 3D package architecture that includes a glass dielectric material with a copper pillar pre-formed therein. The copper pillar may be formed in the incoming core material with through-glass via (TGV) techniques.

Additionally, in some embodiments the first layer interconnect (FLI) side of the dual-sided interconnect die may initially face down and attach to a glass carrier, which in turn may make the FLI side of the 3D package flat.

It will be understood that although embodiments herein may be described with respect to dual-sided interconnect die, that category of interconnect die is intended only as one example. Other embodiments may use legacy interconnect dice or some other type of 3D package that may otherwise need a carrier to handle or that has a high requirement on thickness variation and warpage.

Embodiments herein may provide a number of advantages. For example, the use of the glass dielectric with the dual-sided interconnect die may allow for a higher input/output (I/O) density to be implemented. Additionally, embodiments herein may reduce the risk of either Chip area thickness variation (CTV) or bump thickness variation (BTV). Embodiments herein may not include any, or may include reduced, planarization steps. Die assembly may be performed on known good substrates rather than legacy procedures where die yield loss may have been caused by additional substrate processes after die assembly. No DBF may be needed, so DBF undercut may be reduced or eliminated. No via reveal may be necessary, so via reveal issues caused by alignment problems may be reduced or eliminated.

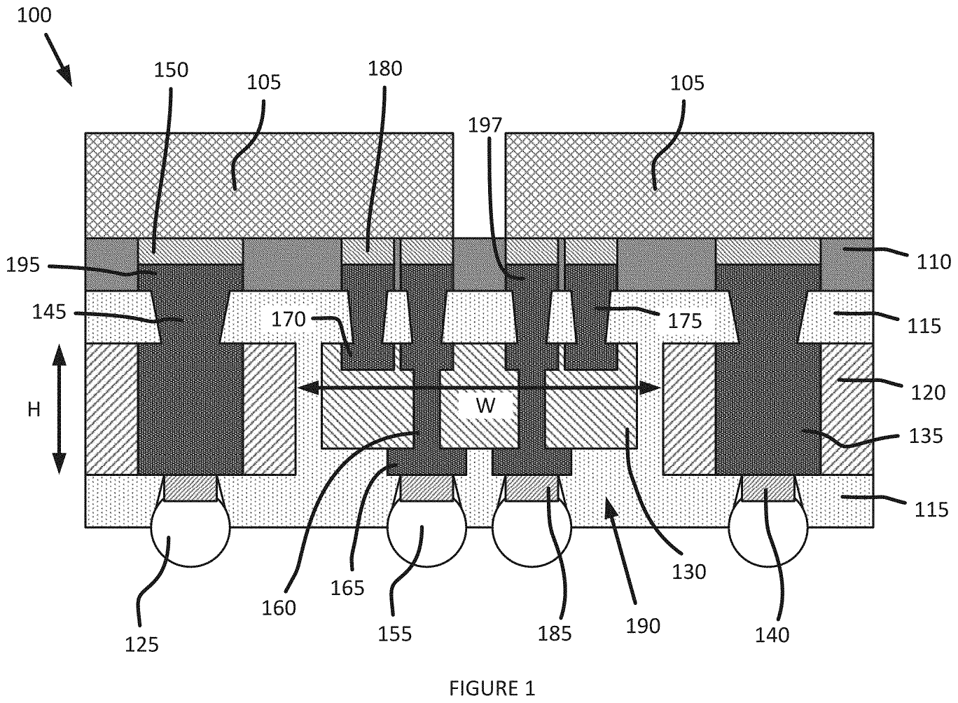

FIG. 1 depicts an example simplified cross-sectional view of a 3D package 100 that may include a dual-sided interconnect die 130, in accordance with various embodiments. Specifically, in some embodiments the package 100 may include the dual-sided interconnect die 130 in a cavity 190 of a glass dielectric 120, as shown in FIG. 1.

Generally, the package 100 may include one or more dies 105. A die 105 may be, for example, an element of a computing system such as a memory die, a processor, a central processing unit (CPU), a controller, some type of logic, or some other type of die. In embodiments, both of the dies 105 may be the same type of element of a computing system, while in other embodiments the dies 105 may be different elements from one another. The dies 105 may include a plurality of die pads (not shown for the sake of clarity of the Figure). Generally, the die pads may be formed of a conductive material such as gold, copper, or some other type of conductive material. The dies 105 may be able to receive or transmit one or more data signals, power signals, or some other type of signal through the die pads.

The die pads of the die may be coupled with surface finish layer 150 and 180. Specifically, the surface finish layer 150 and 180 may be formed out of a surface finish material such as nickel, palladium, gold, an organic surface finish, organic solderability preservatives (OSP), or some other material.

The surface finish layers 150 and 180 may be respectively coupled with with via pads 195 and 197, which may in turn be coupled with plated vias 145 and 175, respectively. It will be understood that in embodiments via pads 195 and 197 may not be present, and instead the surface finish layer 150 and 180 may be directly coupled with plated vias 145 and 175.

The plated vias 145/175 may be plated vias in an organic dielectric 115. The organic dielectric may be, for example, Ajimoto build-up film (ABF), photo imageable dielectric (PID), dry-film photoresist, a mold, or some other type of organic dielectric. In embodiments, vias may be formed by chemical etching, mechanical etching, mechanical drilling, a light-based etching process, photo-lithography, or some other type of via formation technique. The vias may then be filled or plated through techniques such as electroplating, deposition, etc. to generate plated vias 145/175 that provide a conductive pathway. As can be seen in FIG. 1, the plated vias 145/175 may be generally sloped such that they are wider at a part of the organic dielectric 115 closest to the dies 105. However, in other embodiments the plated vias 145/175 may be generally vertical, may be sloped such that they are wider at a portion of the plated vias further from the dies 105, may have curved sides, or may have some other shape. In embodiments, the plated vias 145/175 may have a generally circular cross-section while in other embodiments the vias plated 145/175 may have a differently shaped cross-section such as generally square, rectangular, triangular, etc.

The package 100 may also include an underfill material 110. In embodiments, the underfill material 110 may be, for example, an epoxy. In some embodiments the epoxy may include one or more inorganic fillers such as silica fillers. Generally, the underfill material 110 may be to surround the surface finish layers 150/180 and the via pads 195/197. More generally, the underfill material 110 may fill in any space between the dies 105 and the organic dielectric material 115. As such, the underfill material 110 may provide increased structural stability to the package 100 by prevent a voided space that could otherwise be prone to warping or cracking. Additionally, the underfill material 110 may protect the surface of the dies 105, the surface finish layers 150/180, or the via pads 195/197. In some embodiments, the underfill material 110 may be placed on the dies 105 or the organic dielectric 115 prior to coupling the dies 105 to the organic dielectric 115. In other embodiments, the underfill material 110 may be added to the package 100 after the dies 105 are coupled with the organic dielectric 115. For example, after the dies 105 are coupled with the organic dielectric 115, the underfill material 110 may be injected between the two elements, or otherwise inserted in some other manner. For example, the underfill material 110 may be injected and then a cure may be performed to harden the underfill material 110.

The package 100 may further include a glass dielectric 120 with a cavity 190 therein. The cavity 190 may have a width (as indicated by the designation “W” in FIG. 1) of between approximately 15 millimeters (mm) and approximately 25 mm. The dual-sided interconnect die 130 may be positioned within the cavity 190.

Generally, the glass dielectric 120 may have a height (as indicated by the designation “H” in FIG. 1) of between approximately 100 micrometers (“microns” or “um”) and approximately 200 microns. More specifically, in embodiments the glass dielectric 120 may have a height of approximately 100 microns, though it will be recognized that in other embodiments the glass dielectric 120 may have a different height. Generally, the height of the glass dielectric 120 may be based on characteristics of the package 100 such as strength or flexibility requirements of the package, the height of the dual-sided interconnect die 130, or some other characteristic.

Although the glass dielectric 120 is described herein as “glass,” the glass dielectric 120 may be made of a variety of crystalline structures. For example, in some embodiments the glass dielectric 120 may be formed of fused quartz, which may have a dielectric constant (relative to vacuum) of approximately 3.8 and a loss tangent of approximately 0.0002 at 100 Megahertz (MHz) and 0.00006 at 3 Gigahertz (GHz). In other embodiments, the glass dielectric 120 may be formed of a glass material such as barium borosilicate which may have a dielectric constant of approximately 5.75 and a loss tangent of approximately 0.0036 at 10 GHz. In other embodiments, the glass dielectric may be some appropriate crystalline or non-crystalline material with similar dielectric constants or loss tangents. Generally, the glass dielectric may be some type of rigid material that is handleable without a carrier.

The dual-sided interconnect die 130 may be, for example, an interconnect structure that has interconnect pads on both sides of the dual-sided interconnect die 130. Specifically, as shown in FIG. 1, the dual-sided interconnect die 130 may have one or more interconnect pads 170 coupled with plated via(s) 175 at a first side of the dual-sided interconnect die 130. The dual-sided interconnect die 130 may also have a number of interconnect pads 165 at a side of the dual-sided interconnect die 130 opposite the first side.

As can be seen, in some embodiments some of the interconnect pads such as interconnect pads 170 may be recessed within the dual-sided interconnect die 130. Others of the interconnect pads such as interconnect pads 165 may protrude past the surface of the dual-sided interconnect die 130. However, it will be understood that this configuration is merely one example and in other embodiments one or more of interconnect pads 170 may protrude past the surface of the dual-sided interconnect die 130, or one or more of interconnect pads 165 may be recessed within the dual-sided interconnect die 130 in a fashion similar to that of interconnect pads 170.

The dual-sided interconnect die 130 may be an active die. That is, the dual-sided interconnect die 130 may include one or more transistors, processors, logic, or some other “active” element that is capable of performing some type of logic or processing. The dual-sided interconnect die 130 may further include one or more plated vias such as plated vias 160. The dual-sided interconnect die 130 may further include one or more traces or pads internally to the die, neither of which are shown for the sake of clarity of the Figure. Generally, the traces or pads may communicatively couple one or more of the plated vias 160 to one another or to the active element. In some embodiments, the plated vias 160 may couple opposite sides of the dual-sided interconnect die 130. For example, the plated vias 160 may couple interconnect pad 165 with interconnect pad 170, as shown in FIG. 1. It will be understood that this depiction of the dual-sided interconnect die 130 is a simplified depiction, and in other embodiments the die may have more or less pads, vias, etc.

In some embodiments, the first side of the dual-sided interconnect die 130 may have a pitch that is different than the pitch of the second side of the dual-sided interconnect die. Specifically, the interconnect pads 170 may be spaced apart from one another at a pitch, or spacing, that is less than the pitch of interconnect pads 165 as shown in FIG. 1. In some embodiments, the pitch of interconnect pads 170, which may be referred to as the FLI, may be between approximately 20 microns and approximately 60 microns while the pitch of interconnect pads 165, which may be referred to as the middle-layer interconnect (MLI), may be between approximately 100 microns and approximately 150 microns.

The glass dielectric 120 may further include one or more TGVs 135. The TGVs 135 may be vias that are formed in the glass dielectric 120 by a process such as mechanical drilling, laser drilling, chemical or mechanical etching, or some other technique. After the vias are formed in the glass dielectric, a conductive material such as copper, gold, or some other conductive material may be deposited therein. For example, in some embodiments copper may be electroplated within the TGV 135 120 to form a copper pillar. As can be seen, the TGV 135 may be relatively wide compared to plated vias 160. Specifically, the TGV may have a width or diameter (as measured in a direction parallel to width “W”) of between approximately 20 microns and approximately 100 microns. However, the width of the TGV 135 may be significantly lower than the width of copper pillars in legacy packages. This reduced width may allow more copper pillars to be fit in the same surface area than was possible in legacy packages, thereby allowing for reduced pitch of the copper pillars.

The package 100 may further include a plurality of solder bumps on the MLI side of the package 100. Specifically, the package 100 may include a surface finish layer 140 on the MLI side of the TGV 135 and a surface finish layer 185 on the MLI side of the dual-sided interconnect die 130. The surface finish layer 140/185 may be formed of a conductive material such as nickel, palladium, gold, an organic surface finish OSP, etc., and may be coupled with a solder bump such as solder bumps 155 or 125. The solder bumps 125/155 may include materials such as tin, lead, bismuth, copper, combinations thereof, or some other material.

Generally, as can be seen, an element of a computing device communicatively coupled with solder bump 125 may be able to transmit signals such as power signals or data signals to, or receive signals from, a die 105 by solder bump 125, surface finish layer 140, TGV 135, plated via 145, via pad 195, and surface finish layer 150. Similarly, an element of a computing device communicatively coupled with solder bump 155 may be able to transmit signals such as power signals or data signals to, or receive signals from, a die 105 by solder bump 155, surface finish layer 185, interconnect pad 165, plated via 160, interconnect pad 170, plated via 175, via pad 197, and surface finish layer 180.

In some embodiments, one of the die 105 may be communicatively coupled with the other of the die 105. For example, in embodiments a die 105 may be able to send a signal through the surface finish layer 180 to via pad 197, then plated via 175, to interconnect pad 170. Then the signal may transfer through internal traces or vias of the interconnect die 130 to a different interconnect pad 170, then back up through the plated via 175, via pad 197, and surface finish layer 180 into the other die 105.

It will be understood that the embodiment depicted in FIG. 1 is intended as one example. In other embodiments the package 100 may have more or fewer elements than depicted in FIG. 1, or the elements may be in a different configuration. For example, in some embodiments the package 100 may only include a single die 105, or more than two dies 105. In some embodiments the package 100 may include more or fewer surface finish layers, vias, pads, etc., or those elements may be arranged in different configurations. Other variations of a package that includes an interconnect die in a cavity of a glass dielectric may be present in other embodiments.

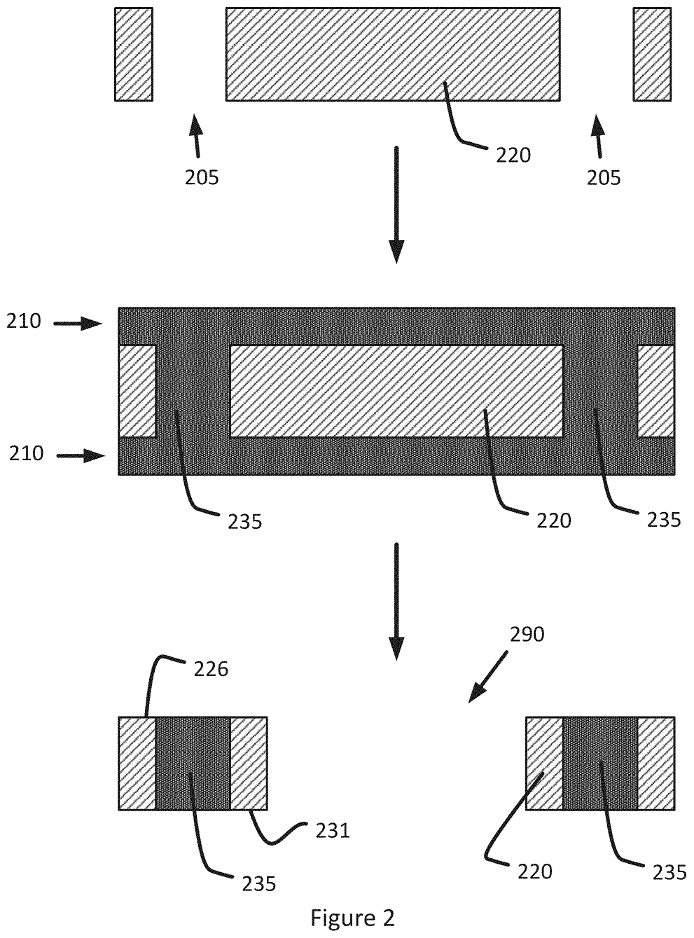

FIG. 2 depicts an example simplified cross-sectional view of one technique by which the glass dielectric 120 may be formed. Specifically, FIG. 2 depicts an example cross-sectional view of a glass dielectric 220 that may be similar to glass dielectric 120. Initially, one or more vias 205 may be formed in the glass dielectric 220. As noted above, the vias 205 may be formed by mechanical drilling, laser etching, mechanical etching, chemical etching, etc.

A conductive material may then be placed on the glass dielectric 220. The conductive material may be, for example, copper, gold, or some other material. The conductive material may be placed on the glass dielectric 220 by a technique such as electroplating, spray deposition, lamination, etc. The conductive material may form TGVs 235, which may be similar to TGVs 135 of FIG. 1. The conductive material may also form outer layers 210 of the conductive material on either side of the glass dielectric 220.

The outer layers 210 of the conductive material may be removed by a process such as mechanical grinding, chemical etching, scraping, planing, etc. such that the outer surfaces 226 and 231 of the glass dielectric 220 are exposed and the TGVs 235 are present in the glass dielectric 220. A cavity 290, which may be similar to cavity 190, may be formed in the glass dielectric 220. Specifically, the cavity 290 may be formed by one or more of the various techniques described above such as mechanical drilling, etching, etc.

It will be understood that this technique is only intended as one example. In other embodiments certain portions of the technique may be performed in a different order or in conjunction with one another. For example, in some embodiments the cavity 290 may be formed simultaneously with the formation of the vias 205. Other variations in this technique may occur in other embodiments.

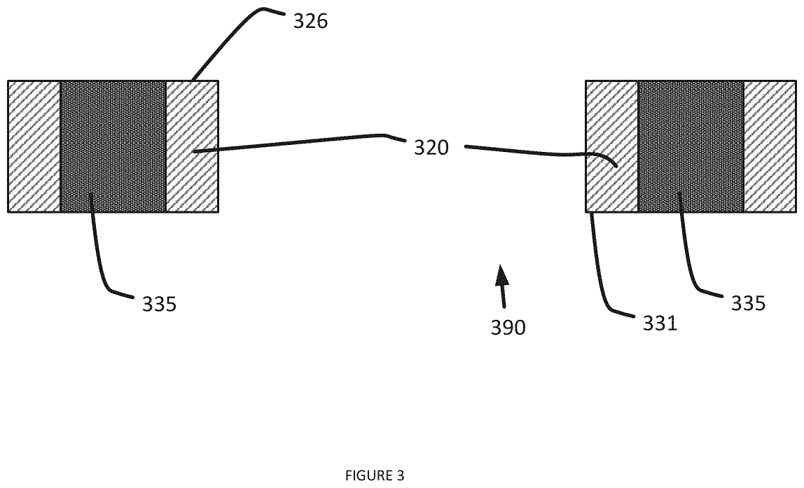

FIGS. 3-11 depict a simplified example process by which a 3D package such as package 100 may be manufactured. In some embodiments, the process may include the above-described elements of FIG. 2, while in other embodiments the process may exclude the above-described elements of FIG. 2. Generally, descriptions of elements in a previous Figure may carry over to a later Figure, and a specific element may not be re-enumerated for the sake of clarity and brevity.

The process may begin at FIG. 3 with a glass dielectric that may be similar to glass dielectrics 120 or 220. The glass dielectric 320 may have TGVs 335 which may be similar to TGVs 135 or 235. The glass dielectric 320 may also have a cavity 390 which may be similar to cavity 190 or 290. The glass dielectric 320 may also have outer surfaces 326 and 331 which may be similar to outer surfaces 226 and 231.

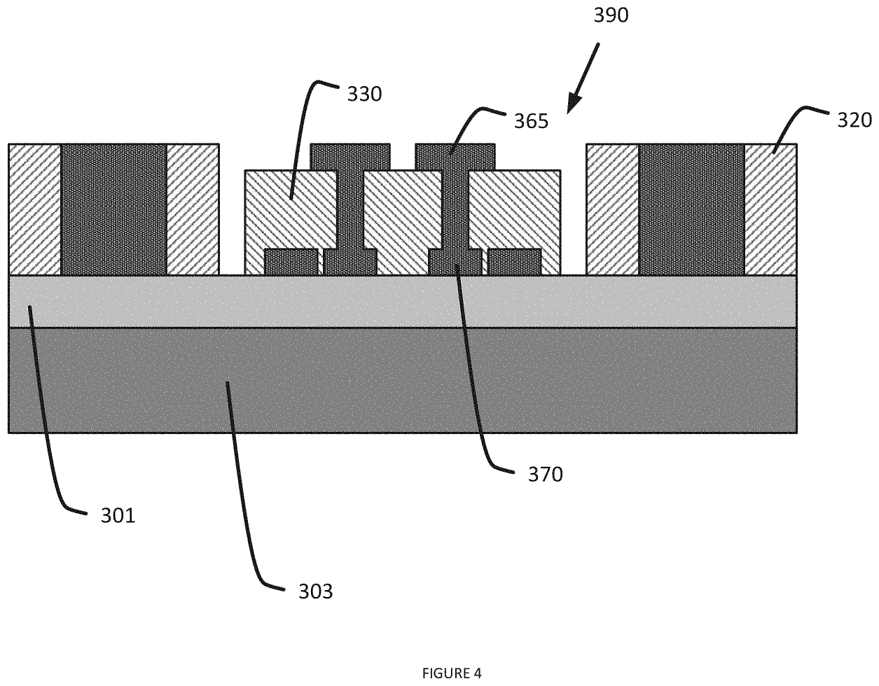

As shown in FIG. 4, the glass dielectric 320 may be coupled with a carrier 303. The carrier 303 may be, for example, a silicon-based substrate, plastic, metal, glass, an organic board, or some other type of carrier. In some embodiments, it may be desirable for the carrier 303 to be glass as the glass carrier 303 may be flatter than alternative materials.

The glass dielectric 320 may be coupled with the carrier 303 by an adhesive 301 placed therebetween. The adhesive 301 may be, for example, a dual-sided adhesive that is able to removably couple with both the carrier 303 and the glass dielectric 320. In other embodiments, the adhesive 301 may be non-removably coupled with the carrier 303. In some embodiments, the glass dielectric 320 may be bonded with the carrier 303 at a panel level or at a unit level. That is, a plurality of glass dielectrics such as glass dielectric 320 may be bonded with a single carrier such as carrier 303. In other embodiments, only a single glass dielectric 320 may be bonded with carrier 303.

A dual-sided interconnect die 330, which may be similar to dual-sided interconnect die 130, may be placed in cavity 390 and bonded to the carrier 303. Similarly to the glass dielectric 320, the dual-sided interconnect 330 may be bonded directly to the carrier 303 in some embodiments while in other embodiments it may be bonded to the carrier 303 by adhesive 301 such as is shown in FIG. 4. The dual-sided interconnect die 330 may include interconnect pads 365 and 370, which may be respectively similar to interconnect pads 165 and 170.

As can be seen in FIG. 4, the side of the dual-sided interconnect die 330 with interconnect pads 370, which may be considered the FLI-side of the dual-sided interconnect die 330, may be bonded with the carrier 303. As a result, the FLI-side of the resultant package such as package 100 may be flat as will be shown below.

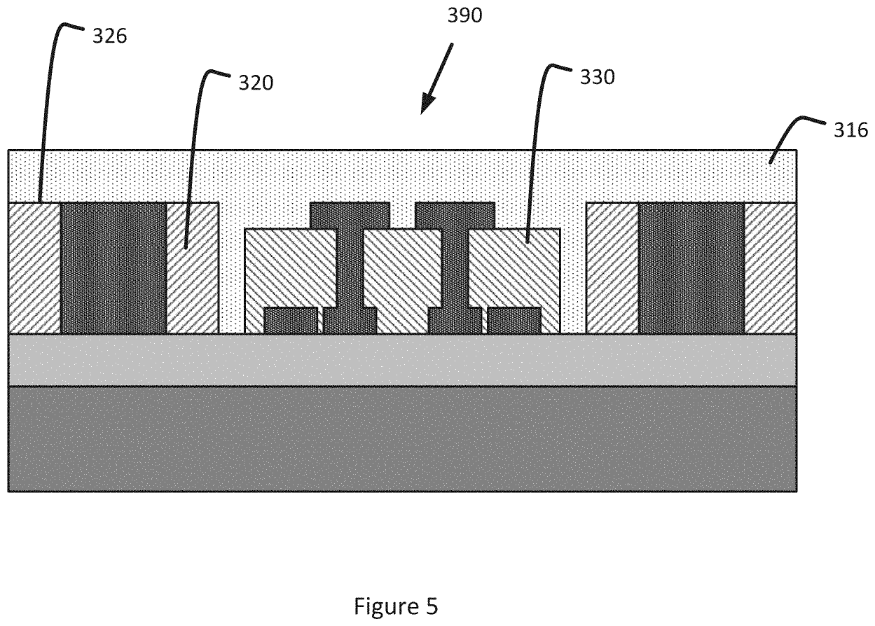

An organic dielectric 316 may then be placed on the glass dielectric 320 and the dual-sided interconnect die 330 as can be seen in FIG. 5. Specifically, the organic dielectric 316 may be a material similar to that of organic dielectric 115, and may be placed on the outer surface 326 of the glass dielectric 320 as well as the MLI layer of the dual-sided interconnect die 330. The organic dielectric 316 may be placed on the glass dielectric 320 and the dual-sided interconnect die 330 through lamination, spray deposition, or some other technique. In some embodiments the organic dielectric 316 may flow into the cavity 390 and fill spaces between the dual-sided interconnect die 330 and the glass dielectric 320 within the cavity 390 as can be seen in FIG. 5. In some embodiments, the organic dielectric 316 may be subjected to surface grinding if, for example, the thickness variation through the organic dielectric 316 is not satisfactory.

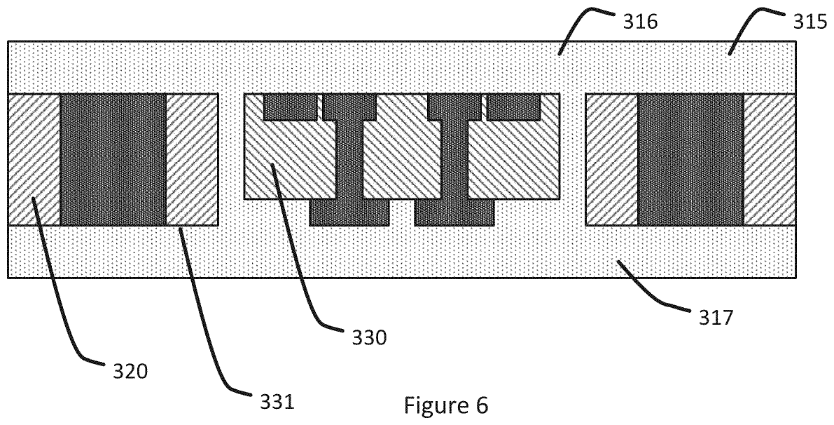

The carrier 303 and the adhesive 301 may then be removed as shown in FIG. 6 and an additional layer of organic dielectric 317 may be applied to the FLI side of the dual-sided interconnect die 330 and the outer surface 331 of the glass dielectric 320. The organic dielectric 317 may be the same type of organic dielectric as organic dielectric 316, or it may be a different type of organic dielectric. The organic dielectric 317 may be deposited by a technique or process such as those described above with respect to organic dielectric 316. The organic dielectrics 316 and 317 may together form organic dielectric 315, which may be similar to organic dielectric 115. In some embodiments, the application of the organic dielectric 317 may include coupling the organic dielectric 316 to another carrier such as carrier 303. Similarly, the organic dielectric 317 may be subjected to surface grinding if the thickness variation of the organic dielectric 317 is not satisfactory.

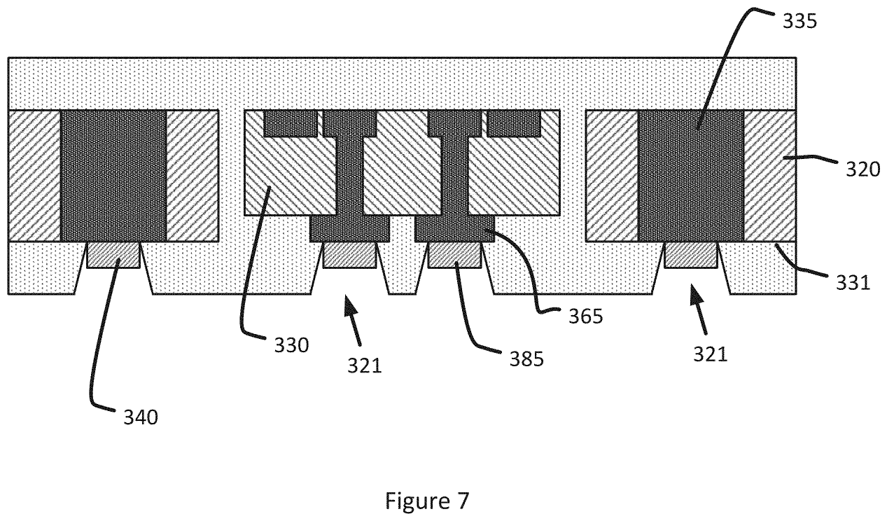

FIGS. 7-9 illustrate one option that can then follow FIG. 6. Specifically, FIGS. 7-9 illustrate one technique by which a package such as package 100 with solder bumps such as solder bumps 155 may be formed. Specifically, as illustrated in FIG. 7, vias such as vias 321 may be formed. Specifically, the vias 321 may be formed such that the side of the TGV 335 that is adjacent to outer surface 331 of the glass dielectric 320 may be exposed. Similarly, the vias 321 may be formed such that the interconnect pads 365, which may be similar to interconnect pads 165, may be exposed. Specifically, the interconnect pads 365 may be on the MLI side of the dual-sided interconnect die 330. The vias 321 may be formed using one or more techniques such as chemical etching, mechanical etching, optical etching or cutting, mechanical drilling, etc.

A surface finish layer such as surface finish layer 340 (which may be similar to surface finish layer 140) or surface finish layer 385 (which may be similar to surface finish layer 185) may then be positioned on the TGV 335 and the interconnect pad 365, respectively, within vias 321. The surface finish layers 340 or 385 may be positioned on the TGV 335 and the interconnect pad 365 through techniques such as electroplating, spray deposition, or some other technique.

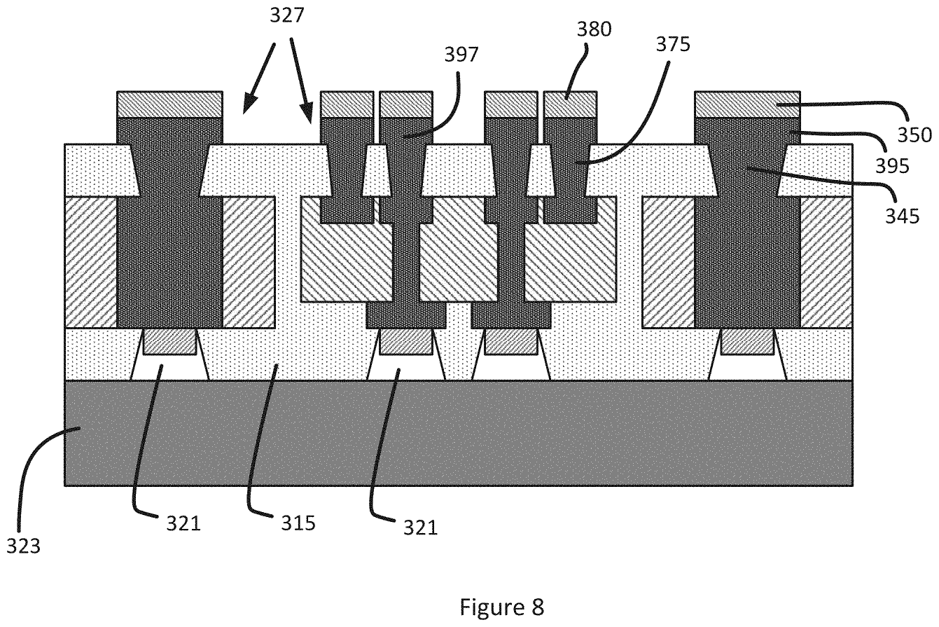

As can be seen in FIG. 8, a protective layer such as protective layer 323 may then be placed on the organic dielectric 315. Specifically, the protective layer 323 may be placed over the organic dielectric 315 such that the protective layer 323 protects vias 321. The protective layer 323 may be formed of, for example, poly-ethylene terephthalate (PET), some other plastic, or some other type of protective material. Specifically, the protective layer 323 may protect the MLI side of the organic dielectric 315 and vias 321 from subsequent processing steps until the protective layer 323 is removed. The protective layer 323 may be placed on the organic dielectric 315 by lamination, spray deposition, or some other technique or process.

One or more vias 327 may be formed on the FLI side of the organic dielectric 315 by a technique such as mechanical or chemical etching, optical etching, mechanical drilling, etc. The vias 327 may then be plated to form plated vias 345 and 375, which may be similar to plated vias 145 and 175, respectively. Specifically, a metal such as copper, gold, or some other conductive material may be electro plated into the vias 327 to form plated vias 345 and 375. It will be understood, however, that in other embodiments some other technique may be used to deposit the conductive material into vias 327 to form plated vias 345 and 375.

During formation of the plated vias 345 and 375, the via pads 397 and 395 may be formed, which may be similar to via pads 197 and 195, respectively. Specifically, the via pads 397 and 395 may be formed during the plating or deposition process that forms plated vias 345 and 375. Surface finish layers 380 and 350, which may be respectively similar to surface finish layers 180 and 150, may then be placed on via pads 397 and 395. The surface finish layers 380 and 350 may be placed on the via pads 397 and 395 by spray deposition, electroplating, reflow, etc.

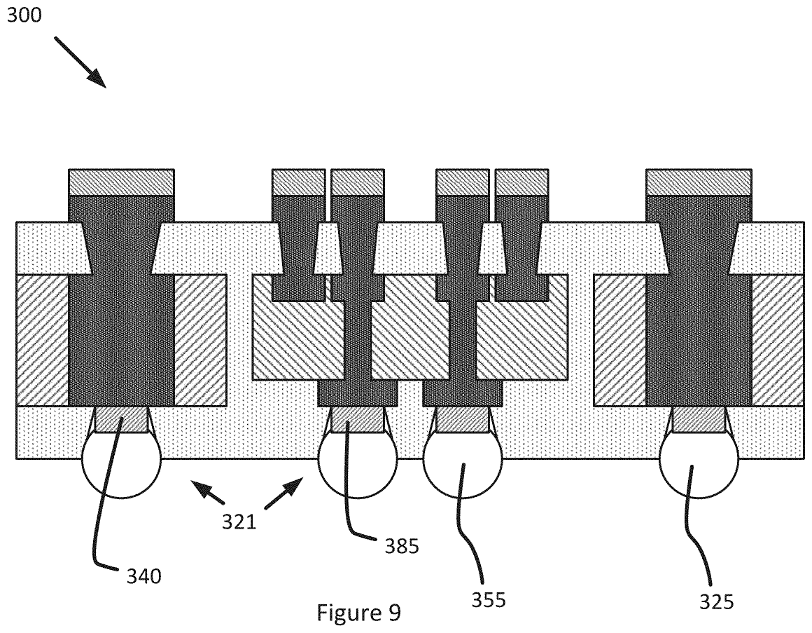

As can be seen in FIG. 9, the protective layer 323 may be removed and solder bumps such as solder bumps 355 and 325 may be placed within vias 321. The solder bumps 355 and 325 may be similar to solder bumps 155 and 125, respectively. The solder bumps 355 and 325 may be coupled with surface finish layer 385 and surface finish layer 340, respectively, for example by a reflow process or some other process to produce package 300.

The techniques depicted in FIGS. 3-9 may produce a package 300 that may be similar to package 100. Further processing may be performed on package 300 to, for example, couple a die (e.g., die 105) with the various surface finish layers 350/380. Additionally or alternatively, an underfill (e.g., underfill 110) may be introduced to package 300.

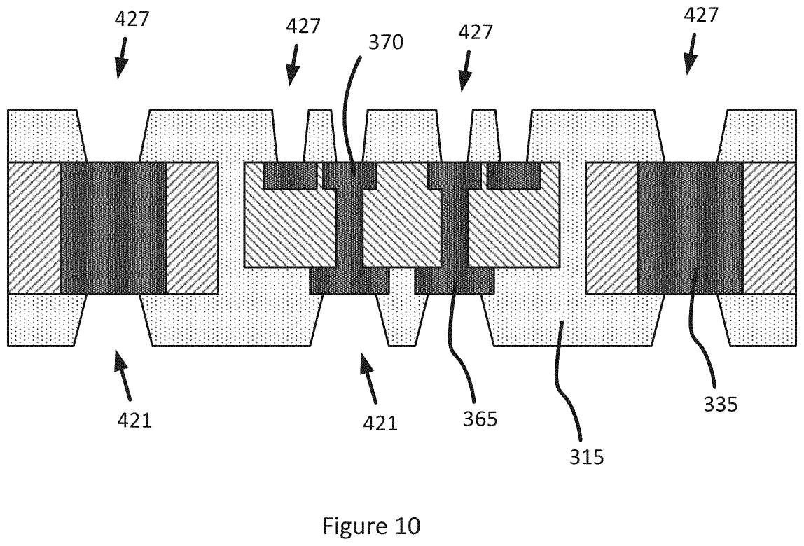

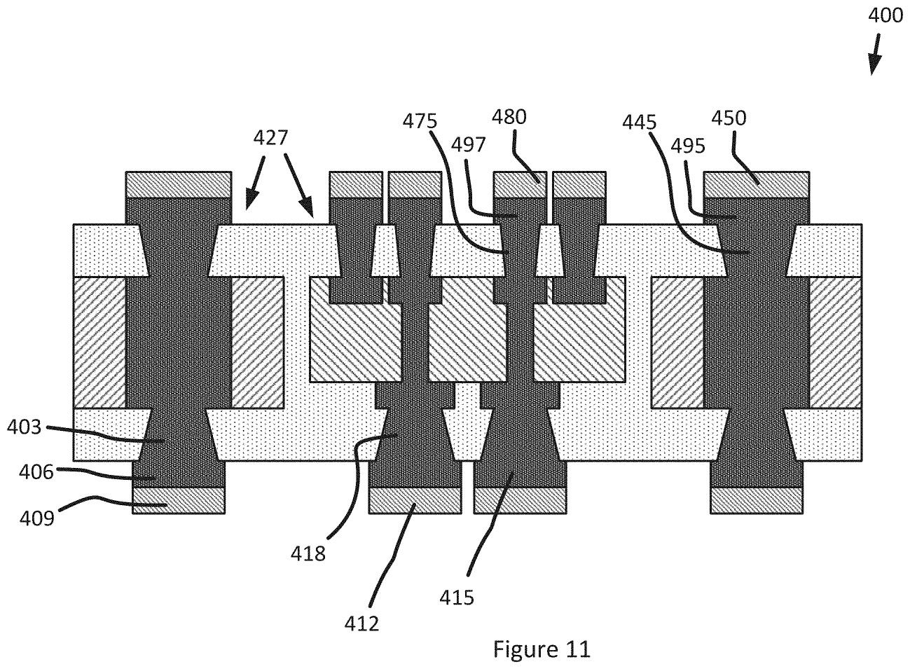

FIGS. 10 and 11 illustrate an alternative option that may follow from FIG. 6 to generate an alternative package 400 as can be seen in FIG. 11. Specifically, as can be seen in FIG. 10, vias 421 (which may be similar to vias 321) may be formed in the MLI side of the organic dielectric 315 to expose the MLI side of the TGV(s) 335 and the interconnect pad(s) 365.

Similarly, vias 427, which may be similar to vias 327, may be formed in the FLI side of the organic dielectric 315 to expose the FLI-side of the TGV(s) 335 and the interconnect pad(s) 370. Specifically, in embodiments the vias 427 may be formed through one or more of the techniques or processes described above such as mechanical, chemical, or optical etching, drilling, cutting, etc.

As can be seen in FIG. 11, the vias 427 and 421 may then be filled to form plated vias and via pads in package 400. Specifically, plated vias 475 and 445 and via pads 497 and 495, which may be respectively similar to plated vias 375 and 345 and via pads 397 and 398, may be formed through one or more of the techniques discussed above such as spray deposition, electroplating, etc. Subsequent to formation of the via pads 495 and 497, surface finish layers 480 and 450 may be respectively placed on the via pads 495 and 497. The surface finish layers 480 and 450 may be similar to surface finish layers 380 and 350 and may include a conductive material such as copper, gold, a solder material such as lead, tin, bismuth, combinations thereof, etc. The surface finish layers 480 and 450 may be placed on the via pads 495/497 through electroplating, spray deposition, a reflow process, etc.

Similarly, plated vias 403 and 418 and via pads 406 and 415 may be formed in vias 421 on the MLI side of the package through techniques such as spray deposition, electroplating, etc. Surface finish layers 409 and 412 may be respectively placed on via pads 406 and 415 through similar techniques such as spray deposition, electroplating, reflow, etc. The surface finish layers 409 and 412 may be composed of a conductive material similar to that of previously-described surface finish layers such as nickel, palladium, gold, an organic surface finish OSP, etc.

It can be seen that package 400 may include elements different than those of packages 100 or 300. Specifically, package 400 may include plated vias 403/418, via pads 406/415, and surface finish layers 409/412 on the MLI side of the package 400 instead of, for example, solder bumps such as solder bumps 355 or 325.

It will be understood that the above-described elements of FIGS. 1-11 are intended as illustrative, and other embodiments may have variations on the above-described Figures. For example, in some embodiments the FLI side of a package may include a solder bump such as solder bumps 355 or 325. In some embodiments, more or fewer elements such as various vias, pads, etc. may be present. Some embodiments may have an additional dual-sided interconnect die within a cavity of the glass dielectric. Some embodiments have utilize a glass dielectric with an interconnect structure that is not dual-sided. Additionally, in some embodiments elements that are depicted as occurring in one sequence or simultaneously, for example the formation or plating of vias 421 and 427, may occur in sequence rather than simultaneously.

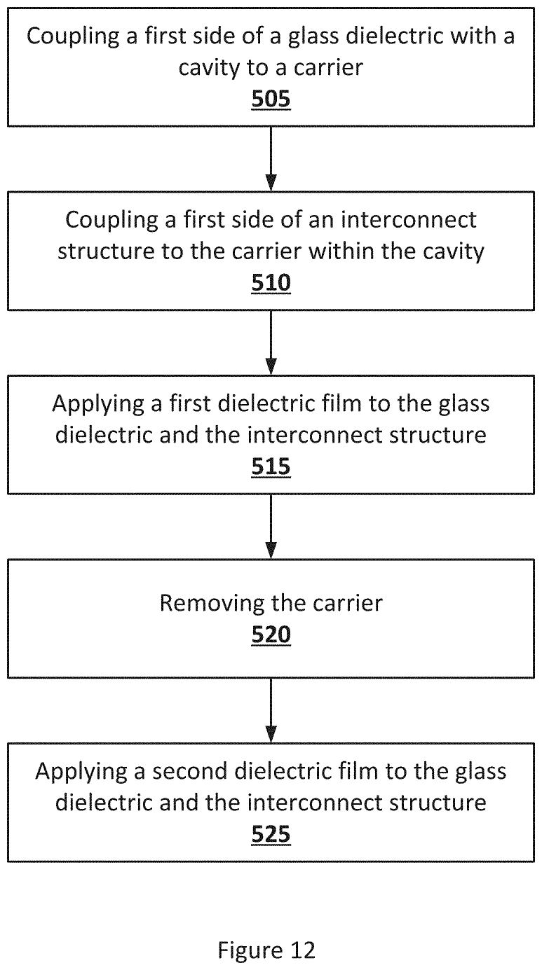

FIG. 12 illustrates an example technique that may relate to aspects of FIGS. 2-11. Specifically, the technique may include coupling, at 505, a first side of a glass dielectric with a cavity to a carrier. The glass dielectric may be, for example, glass dielectric 320, which may include a cavity such as cavity 390. The glass dielectric may be coupled with a carrier such as carrier 303. In some embodiments the glass dielectric may be coupled directly with the carrier, while in other embodiments the glass dielectric may be coupled with the carrier by an adhesive such as adhesive 301.

The technique may further include coupling, at 510, a first side of an interconnect structure to the carrier within the cavity. The interconnect structure may be, for example, a dual-sided interconnect die such as dual-sided interconnect die 330 as shown in FIG. 4. However, in other embodiments the interconnect structure may be some other type of interconnect structure such as a single-sided interconnect.

The technique may further include applying, at 515, a first dielectric film to the glass dielectric and the interconnect structure. The first dielectric film may be, for example, organic dielectric 316 as shown in FIG. 5. In some embodiments the dielectric film may be laminated onto the glass dielectric and the interconnect structure, while in other embodiments the dielectric film may be applied through some other technique, as described above.

The technique may further include removing the carrier at 520 and applying a second dielectric film to the glass dielectric and the interconnect structure at 525. The second dielectric film may be, for example, organic dielectric 317 as shown in FIG. 6. Similarly to element 515, the dielectric film may be laminated onto the glass dielectric and the interconnect structure, while in other embodiments the dielectric film may be applied through some other technique.

It will be understood that the technique discussed above with respect to FIG. 12 is intended as only one example, and in other embodiments certain elements may be missing or may be performed in a different order. For example, in some embodiments element 510 may be performed before element 505. That is, the interconnect structure may be coupled with the carrier and then the glass dielectric may be positioned on the carrier such that the interconnect structure is within the cavity of the glass dielectric.

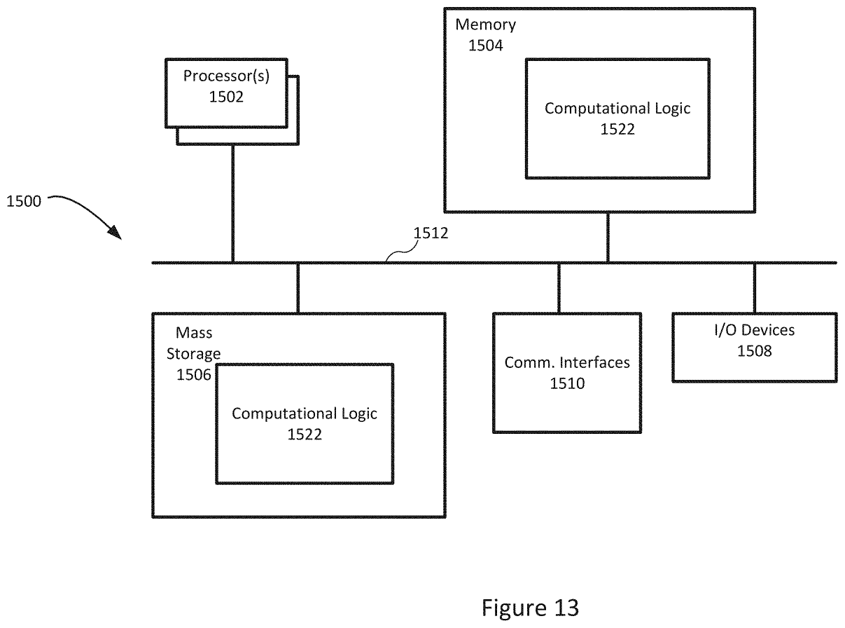

FIG. 13 illustrates an example computing device 1500 suitable for use with packages 100, 300, or 400 (collectively, “the packages”), in accordance with various embodiments. Specifically, in some embodiments, the computing device 1500 may include one or more of the packages therein.

As shown, computing device 1500 may include one or more processors or processor cores 1502 and system memory 1504. For the purpose of this application, including the claims, the terms “processor” and “processor cores” may be considered synonymous, unless the context clearly requires otherwise. The processor 1502 may include any type of processors, such as a CPU, a microprocessor, and the like. The processor 1502 may be implemented as an integrated circuit having multi-cores, e.g., a multi-core microprocessor. The computing device 1500 may include mass storage devices 1506 (such as diskette, hard drive, volatile memory (e.g., DRAM, compact disc read-only memory (CD-ROM), digital versatile disk (DVD), and so forth)). In general, system memory 1504 and/or mass storage devices 1506 may be temporal and/or persistent storage of any type, including, but not limited to, volatile and non-volatile memory, optical, magnetic, and/or solid state mass storage, and so forth. Volatile memory may include, but is not limited to, static and/or DRAM. Non-volatile memory may include, but is not limited to, electrically erasable programmable read-only memory, phase change memory, resistive memory, and so forth.

The computing device 1500 may further include input/output (I/O) devices 1508 (such as a display (e.g., a touchscreen display), keyboard, cursor control, remote control, gaming controller, image capture device, and so forth) and communication interfaces 1510 (such as network interface cards, modems, infrared receivers, radio receivers (e.g., Bluetooth), and so forth).

The communication interfaces 1510 may include communication chips (not shown) that may be configured to operate the device 1500 in accordance with a Global System for Mobile Communication (GSM), General Packet Radio Service (GPRS), Universal Mobile Telecommunications System (UMTS), High Speed Packet Access (HSPA), Evolved HSPA (E-HSPA), or Long-Term Evolution (LTE) network. The communication chips may also be configured to operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chips may be configured to operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication interfaces 1510 may operate in accordance with other wireless protocols in other embodiments.

The computing device 1500 may further include or be coupled with a power supply 1525. The power supply 1525 may, for example, be a power supply that is internal to the computing device 1500 such as a battery. In other embodiments the power supply 1525 may be external to the computing device 1500. For example, the power supply 1525 may be an electrical source such as an electrical outlet, an external battery, or some other type of power supply. The power supply 1525 may be, for example alternating current (AC), direct current (DC) or some other type of power supply. The power supply 1525 may in some embodiments include one or more additional components such as an AC to DC convertor, one or more downconverters, one or more upconverters, transistors, resistors, capacitors, etc. that may be used, for example, to tune or alter the current or voltage of the power supply from one level to another level. In some embodiments the power supply 1525 may be configured to provide power to the computing device 1500 or one or more discrete components of the computing device 1500 such as the processor(s) 1502, mass storage 1506, I/O devices 1508, etc.

The above-described computing device 1500 elements may be coupled to each other via system bus 1512, which may represent one or more buses. In the case of multiple buses, they may be bridged by one or more bus bridges (not shown). Each of these elements may perform its conventional functions known in the art. The various elements may be implemented by assembler instructions supported by processor(s) 1502 or high-level languages that may be compiled into such instructions.

The permanent copy of the programming instructions may be placed into mass storage devices 1506 in the factory, or in the field, through, for example, a distribution medium (not shown), such as a compact disc (CD), or through communication interface 1510 (from a distribution server (not shown)). That is, one or more distribution media having an implementation of the agent program may be employed to distribute the agent and to program various computing devices.

The number, capability, and/or capacity of the elements 1508, 1510, 1512 may vary, depending on whether computing device 1500 is used as a stationary computing device, such as a set-top box or desktop computer, or a mobile computing device, such as a tablet computing device, laptop computer, game console, or smartphone. Their constitutions are otherwise known, and accordingly will not be further described.

In various implementations, the computing device 1500 may comprise one or more components of a data center, a laptop, a netbook, a notebook, an ultrabook, a smartphone, a tablet, a personal digital assistant (PDA), an ultra mobile PC, a mobile phone, or a digital camera. In further implementations, the computing device 1500 may be any other electronic device that processes data.

In some embodiments, as noted above, computing device 1500 may include one or more of the packages. For example, in some embodiments the processor 1502, memory 1504, or some other component of the computing device 1500 may be the die 105. More generally, one of processor 1502, memory 1504, or some other component of the computing device 1500 may be coupled with a surface finish layer such as surface finish layers 150/180, surface finish layers 350/380, or surface finish layers 450/480.

### EXAMPLES OF VARIOUS EMBODIMENTS

Example 1 includes a semiconductor package comprising: a die; a glass core coupled with the die; and an interconnect structure positioned within a cavity of the glass core and communicatively coupled with the die, wherein the interconnect structure is an active interconnect with a first pad on a first side of the active interconnect that faces the die and a second pad on a second side of the active interconnect opposite the first side.

Example 2 includes the semiconductor package of example 1, wherein the interconnect structure has a height of between 100 micrometers and 200 micrometers measured in a direction perpendicular to a face of the die to which the glass core is coupled.

Example 3 includes the semiconductor package of example 1, further comprising an organic dielectric positioned within the cavity and at least partially encapsulating the interconnect structure.

Example 4 includes the semiconductor package of example 3, wherein the first pad is communicatively coupled with the die by a via in the organic dielectric.

Example 5 includes the semiconductor package of any of examples 1-4, wherein the interconnect structure further includes a via that communicatively couples the first pad and the second pad.

Example 6 includes the semiconductor package of any of examples 1-4, wherein the glass core includes a copper-plated through-glass via (TGV).

Example 7 includes the semiconductor package of example 6, wherein the TGV is communicatively coupled with the die by a first via or a first solder bump at a first side of the TGV, and the TGV is further coupled with a second via or a second solder bump at a second side of the TGV opposite the first side.

Example 8 includes the semiconductor package of example 7, wherein the first solder bump or the first via are coupled with a pad of the die.

Example 9 includes the semiconductor package of example 7, wherein a computing component coupled with the second solder bump or the second via is communicatively coupled with the die.

Example 10 includes a method of forming a package with a glass dielectric therein, the method comprising: coupling a first side of the glass dielectric with a cavity to a carrier, wherein the glass dielectric has the first side and a second side opposite the first side; coupling a first side of an interconnect structure to the carrier within the cavity, wherein the interconnect structure has a first side and a second side opposite the first side; applying a first dielectric film to the second side of the glass dielectric and the second side of the interconnect structure; removing the carrier from the glass dielectric and the interconnect structure; and applying a second dielectric film to the first side of the glass dielectric and the first side of the interconnect structure.

Example 11 includes the method of example 10, wherein applying the first dielectric film includes laminating the first dielectric film to the second side of the glass dielectric and the second side of the interconnect structure.

Example 12 includes the method of example 10, wherein applying the second dielectric film includes laminating the second dielectric film to the first side of the glass dielectric and the first side of the interconnect structure.

Example 13 includes the method of example 10, wherein the first dielectric film is an organic dielectric film.

Example 14 includes the method of example 10, wherein the glass dielectric includes a through-glass via (TGV) that communicatively couples a pad at the first side of the glass dielectric with a pad at the second side of the glass dielectric.

Example 15 includes the method of any of examples 10-14, wherein the interconnect structure includes a first pad at the first side of the interconnect structure and a second pad at the second side of the interconnect structure.

Example 16 includes the method of example 15, wherein the interconnect structure includes a via that couples the first pad of the interconnect structure with the second pad of the interconnect structure.

Example 17 includes the method of any of examples 10-14, further comprising: opening a first via in the first dielectric film to expose the second side of the interconnect structure; opening a second via in the second dielectric film to expose the first side of the interconnect structure; and plating the first via.

Example 18 includes the method of example 17, further comprising plating the second via.

Example 19 includes the method of example 17, further comprising coupling a die with the first via such that the die is communicatively coupled with the interconnect structure.

Example 20 includes the method of example 17, further comprising coupling a solder bump with the first side of the interconnect structure within the second via.

Example 21 includes a substrate for coupling with a die, wherein the substrate includes: a glass dielectric layer; and an active interconnect that includes a first pad at a first side of the active interconnect and a second pad at a second side of the active interconnect opposite the first side, wherein the active interconnect is adjacent to the glass dielectric layer in a direction parallel to the first side of the active interconnect.

Example 22 includes the substrate of example 21, wherein the active interconnect is positioned within a cavity of the glass dielectric layer.

Example 23 includes the substrate of example 21, wherein the first side of the active interconnect includes pads at a different pitch than a pitch of pads of the second side of the active interconnect.

Example 24 includes the substrate of any of examples 21-23, further comprising an organic dielectric that at least partially encapsulates the active interconnect.

Example 25 includes the substrate of example 24, further comprising an outer pad at an outer side of the organic dielectric, wherein the outer pad is communicatively coupled with the first pad by a via in the organic dielectric.

Example 26 includes the substrate of example 24, further comprising a solder bump in a via of the organic dielectric, wherein the solder bump is coupled with the first pad within the via.

Example 27 includes a computing device comprising: a die; a board; and an interconnect positioned between and communicatively coupling the die and the board, wherein the interconnect includes: a crystalline dielectric with a cavity therein; and an active interconnect that includes a first pad on a first side of the active interconnect and a second pad on a second side of the active interconnect opposite the first side.

Example 28 includes the computing device of example 27, wherein the first pad is communicatively coupled with the die by a plated via.

Example 29 includes the computing device of example 27, wherein the second pad is communicatively coupled with the board by a plated via.

Example 30 includes the computing device of example 27, wherein the second pad is communicatively coupled with the board by a solder bump.

Example 31 includes the computing device of any of examples 27-30, wherein the crystalline dielectric includes glass.

Example 32 includes the computing device of example 31, wherein the crystalline dielectric has a dielectric constant of between 5.5 and 6.

Example 33 includes the computing device of any of examples 27-30, wherein the crystalline dielectric includes fused quartz.

Example 34 includes the computing device of any of examples 27-30, wherein the crystalline dielectric has a dielectric constant between 3.5 and 4.

Example 35 includes the computing device of any of examples 27-30, wherein the crystalline dielectric includes a through-glass via (TGV) that communicatively couples the die and the board.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations of the present disclosure, including what is described in the Abstract, is not intended to be exhaustive or to limit the present disclosure to the precise forms described. While specific implementations of, and examples for, the present disclosure are described herein for illustrative purposes, various equivalent modifications are possible within the scope of the present disclosure, as those skilled in the relevant art will recognize.

These modifications may be made to the present disclosure in light of the above detailed description. The terms used in the following claims should not be construed to limit the present disclosure to the specific implementations disclosed in the specification and the claims.

1-25. (canceled)

26. A semiconductor package, comprising:
an interconnect die having:
an upper surface;
a lower surface opposite to the upper surface;
a first side-surface between the upper surface and the lower surface; and
a second side-surface between the upper surface and the lower surface, the second side-surface being opposite to the first side-surface;
a first die above the upper surface of the interconnect die, the first die conductively coupled to the interconnect die;
a second die above the upper surface of the interconnect die, the second die conductively coupled to the interconnect die; and
a glass layer below the first die and the second die, the glass layer having:
an opening, the opening having a first opening side-surface and a second opening side-surface;
a first conductive through-glass via; and
a second conductive through-glass via,
wherein:
the interconnect die is at least partially in the opening of the glass layer such that the first side-surface of the interconnect die is adjacent to the first opening side-surface and the second side-surface of the interconnect die is adjacent to the second opening side-surface,
the first opening side-surface is between the first conductive through-glass via and the first side-surface of the interconnect die; and
the second opening side-surface is between the second conductive through-glass via and the second side-surface of the interconnect die.

27. The semiconductor package of claim 26, wherein the glass layer has a thickness of at least 100 microns.

28. The semiconductor package of claim 26, wherein the glass layer comprises boron and silicon.

29. The semiconductor package of claim 28, wherein the glass layer further comprises barium.

30. The semiconductor package of claim 26, wherein the glass layer does not comprise epoxy.

31. The semiconductor package of claim 26, further comprising organic dielectric between the first die or the second die and the glass layer.

32. The semiconductor package of claim 31 wherein:
the organic dielectric is between the first die or the second die and the interconnect die, and
conductive vias through the organic dielectric are coupled to the first die or the second die and the interconnect die.

33. The semiconductor package of claim 26, wherein the first through-glass via and the second through-glass via comprise copper.

34. A semiconductor package substrate, comprising:
a glass layer having a first side, a second side opposite to the first side, and a cavity between the first side and the second side, the cavity being open at least to the first side;
a semiconductor die in the cavity;
a first organic dielectric between a first surface of the semiconductor package substrate and the first side of the glass layer;
a second organic dielectric between a second surface of the semiconductor package substrate and the second side of the glass layer, the second surface of the semiconductor package substrate being opposite to the first surface of the semiconductor package substrate;
conductive pads on the first surface of the semiconductor package substrate; and
conductive vias through the first organic dielectric conductively coupled to the conductive pads and the semiconductor die.

35. The semiconductor package substrate of claim 34, wherein:
the conductive pads are first conductive pads,
the conductive vias are first conductive vias, and
the semiconductor package substrate further comprises:
at least one conductive through-glass via in the glass layer between the first side and the second side of the glass layer;
second conductive pads on the first surface of the semiconductor package substrate;
second conductive vias through the first organic dielectric conductively coupled to the second conductive pads and the at least one conductive through-glass via; and
third conductive pads conductively coupled to the at least one conductive through-glass via on the second side of the glass layer.

36. The semiconductor package substrate of claim 35, wherein a first pitch of the first conductive pads is smaller than a second pitch of the third conductive pads.

37. The semiconductor package substrate of claim 35, wherein:
the semiconductor die comprises:
a first die-surface proximate to the first conductive pads;
a second die-surface opposite to the first die-surface;
fourth conductive pads on the first die-surface;
fifth conductive pads on the second die-surface; and
plated vias through the semiconductor die, the plated vias coupled to the fifth conductive pads and at least some of the fourth conductive pads, and
the first conductive vias are conductively coupled to the fourth conductive pads of the semiconductor die.

38. The semiconductor package substrate of claim 37, wherein a third pitch of the fourth conductive pads is smaller than a fourth pitch of the fifth conductive pads.

39. The semiconductor package substrate of claim 34, wherein:
the semiconductor die has side-surfaces perpendicular to the first side and the second side of the glass layer, and
the semiconductor package substrate further comprises a third organic dielectric in the cavity in contact with the side-surfaces of the semiconductor die.

40. The semiconductor package substrate of claim 39, wherein the first organic dielectric is same as the third organic dielectric.

41. A semiconductor package, comprising:
a package substrate having:
first conductive pads on a first surface;
second conductive pads on a second surface, the second surface being opposite to the first surface;
conductive pathways conductively coupled to the first conductive pads and the second conductive pads;
a solid volume of glass between the first surface and the second surface; and
organic dielectric on either side of the solid volume of glass, the organic dielectric being between the solid volume of glass and the first surface of the package substrate on one side and between the solid volume of glass and the second surface of the package substrate on an opposing side; and
a first die coupled to the first conductive pads,
wherein:
at least some of the conductive pathways comprise conductive through-glass vias in the solid volume of glass, and
at least some other of the conductive pathways comprise conductive vias through the organic dielectric.

42. The semiconductor package of claim 41, wherein at least some of the conductive through-glass vias have larger diameters than at least some of the conductive vias.

43. The semiconductor package of claim 41, wherein a first pitch of the first conductive pads is smaller than a second pitch of the second conductive pads.

44. The semiconductor package of claim 41, wherein at least some of the second conductive pads are directly coupled to the conductive through-glass vias.

45. The semiconductor package of claim 41, wherein the solid volume of glass comprises boron and silicon.
